(19) United States
(12) Patent Application Publication
(10) Pub. No.: US 2025/0233032 A1
(43) Pub. Date: Jul. 17, 2025

(54) DOUBLE-SIDED COOLING SEMICONDUCTOR DEVICE

(71) Applicant: POWER MASTER SEMICONDUCTOR CO., LTD., Cheongju-si (KR)

(72) Inventors: Ki-Myung YOON, Bucheon-si (KR); In-Suk KIM, Bucheon-si (KR); Jooyaung EOM, Gimpo-si (KR)

(21) Appl. No.: 18/702,004

(22) PCT Filed: Dec. 8, 2022
(86) PCT No.: PCT/KR2022/019885

§ 371 Date: Apr. 17, 2024

(30) Foreign Application Priority Data
Dec. 10, 2021 (KR) 10-2021-0176931

(51) Int. Cl. H01L 23/24; H01L 21/48; H01L 23/00; H01L 23/367; H01L 23/373; H01L 23/498; H01L 25/07; H10D 80/20

(52) U.S. Cl. CPC H01L 23/24; H01L 21/4853; H01L 23/3677; H01L 23/3735; H01L 23/49844; H01L 25/072; H01L 24/32; H01L 24/48; H01L 24/73; H01L 2224/32245; H01L 2224/48245; H01L 2224/48472; H01L 2224/73215; H01L 2224/73265; H01L 2924/10272; H01L 2924/13055; H10D 80/20

(57) ABSTRACT

Provided is a double-sided cooling semiconductor device. The device includes: a board; a semiconductor chip disposed on the board; an external connection frame disposed on the semiconductor chip; a spacer disposed on the external connection frame; and a molding part filling a space between the board and the spacer, wherein a lower surface of the board is exposed to the outside through a lower surface of the molding part, and an upper surface of the spacer is exposed to the outside through an upper surface of the molding part.

### TECHNICAL FIELD

The disclosure relates to a double-sided cooling semiconductor device.

### BACKGROUND ART

A power semiconductor may convert power supplied from the power source or battery of any device using power to voltage and current levels required by any of various systems (for example, an automobile), and manage power of an entire system. The power semiconductor may be used in the form of a module in which individual elements, integrated circuits, and multiple elements are integrated into a package based on its application purpose and voltage resistance feature. The power semiconductor is required to be able to be operated in a harsh environment having a high operation temperature and a long operation time, thus requiring high reliability. In this regard, research is actively being conducted on a method of cooling a semiconductor device on a double side to cope with high heat generation of the power semiconductor.

### DISCLOSURE

### Technical Problem

The disclosure attempts to provide a double sided cooling semiconductor device which may exhibit a lower current loss and excellent heat dissipation by adopting a spacer having an electrical insulation feature and a high heat conduction feature.

### Technical Solution

According to an embodiment, provided is a double sided cooling semiconductor device including: a board; a semiconductor chip disposed on the board; an external connection frame disposed on the semiconductor chip; a spacer disposed on the external connection frame; and a molding part filling a space between the board and the spacer, wherein a lower surface of the board is exposed to the outside through a lower surface of the molding part, and an upper surface of the spacer is exposed to the outside through an upper surface of the molding part.

The spacer may include at least one material selected from aluminum oxide (Al₂O₃), aluminum nitride (AlN), and silicon nitride (Si₃N₄).

The lower surface of the board, which is exposed to the outside through the lower surface of the molding part, may be connected to a first external cooling structure to dissipate heat, and the upper surface of the spacer, which is exposed to the outside through the upper surface of the molding part, may be connected to a second external cooling structure to dissipate heat.

A bondable metal layer capable of being soldered or sintered may be disposed between the spacer and the external connection frame, and the spacer and the external connection frame may be bonded to each other through soldering or sintering.

The bondable metal layer may be applied to a lower surface of the spacer.

The spacer and the external connection frame may be bonded to each other through direct copper bonding or active metal brazing.

The spacer may include the lower spacer and the upper spacer, and the lower spacer and the upper spacer may be bonded to each other through direct copper bonding or active metal brazing.

The lower spacer may include at least one material selected from aluminum oxide (Al₂O₃), aluminum nitride (AlN), and silicon nitride (Si₃N₄), and the upper spacer may include at least one material selected from copper (Cu) and aluminum (Al).

The spacer may include an insulating material made of ceramic and includes a curved part.

The lower spacer may include an insulating material made of ceramic, and the upper spacer may include at least one material selected from copper (Cu) and aluminum (Al).

The spacer may include the lower spacer, the middle spacer, and the upper spacer, and the lower spacer, the middle spacer, and the upper spacer may be bonded to one another through direct copper bonding or active metal brazing.

The lower spacer and the upper spacer may each include at least one material selected from copper (Cu) and aluminum (Al), and the middle spacer may include an insulating material made of ceramic.

The board may be a direct bonded copper (DBC) board, and the board may include a first metal layer, a second metal layer, and a ceramic layer formed between the first metal layer and the second metal layer.

The semiconductor chip may include a first semiconductor chip having a first width, and a second semiconductor chip having a second width greater than the first width, the spacer may include the first spacer having a third width corresponding to the first width, and the second spacer having a fourth width corresponding to the second width and larger than the third width, and the external connection frame may have a lower surface bonded to both the first semiconductor chip and the second semiconductor chip and an upper surface bonded to both the first spacer and the second spacer.

### DESCRIPTION OF THE DRAWINGS

FIG. 1 is a diagram for explaining a double sided cooling semiconductor device according to an embodiment.

FIG. 2 is a diagram for explaining a double sided cooling semiconductor device according to an embodiment.

FIG. 3 is a diagram for explaining a double sided cooling semiconductor device according to an embodiment.

FIG. 4 is a diagram for explaining a double sided cooling semiconductor device according to an embodiment.

FIG. 5 is a diagram for explaining a double sided cooling semiconductor device according to an embodiment.

### MODE FOR INVENTION

Hereinafter, embodiments of the disclosure will be described in detail with reference to the accompanying drawings so that those skilled in the art to which the disclosure pertains may easily practice the disclosure. However, the disclosure may be modified in various different forms, and is not limited to the embodiments described herein. In addition, in the drawings, portions unrelated to the description will be omitted to obviously describe the disclosure, and similar reference numerals will be used to describe similar portions throughout the present specification.

Through the specification and the claims, unless explicitly described otherwise, “including” any components will be understood to imply the inclusion of another component rather than the exclusion of another component.

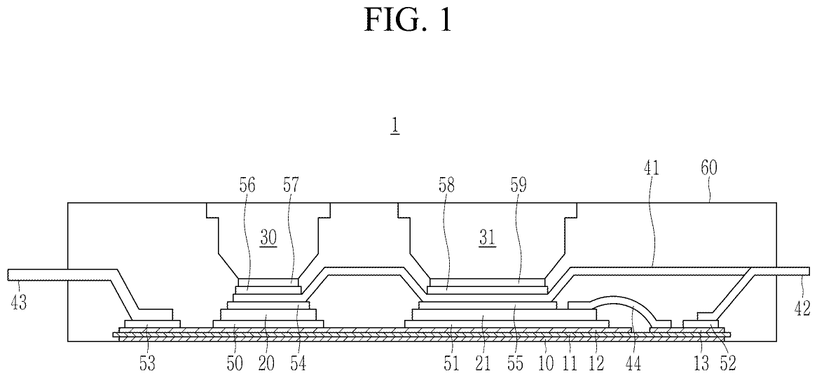

FIG. 1 is a diagram for explaining a double sided cooling semiconductor device according to an embodiment.

Referring to FIG. 1, a double sided cooling semiconductor device 1 according to an embodiment may include boards 10, 11, 12, and 13, semiconductor chips 20 and 21, spacers 30 and 31, external connection frames 41, 42, and 43, a wire connection part 44, bonding layers 50, 51, 52, 53, 54, 55, 56, and 58, bondable metal layers 57 and 59, and a molding part 60.

The board 10, 11, 12, or 13 may be a direct bonded copper (DBC) board. In detail, the board may include a first metal layer 10, second metal layers 12 and 13, and a ceramic layer 11 formed between the first metal layer 10 and the second metal layer 12 or 13. In general, the first metal layer 10 and the second metal layers 12 and 13 may each include copper (Cu), and the scope of the disclosure is not limited thereto. The scope of the board in the disclosure is not limited to the DBC board, and the board may be implemented as a printed circuit board (PCB), a heat spreader, a heat sink, a lead, or the like.

The semiconductor chips 20 and 21 may be disposed on the boards 10, 11, 12, and 13. In general, the double sided cooling semiconductor device may require the plurality of semiconductor devices 20 and 21 to be disposed in the form of multiple chips to satisfy its electrical specification. Here, the semiconductor chips 20 and 21 may be power semiconductor chips (or power devices). For example, the semiconductor chip 20 or 21 may include any of various types of power devices including an insulated gate bipolar transistor (IGBT) and a silicon carbide (SiC) device.

The semiconductor chip 20 or 21 may be bonded to the boards 10, 11, 12, and 13 through the bonding layer 50 or 51. In detail, the semiconductor chip 20 may be bonded to the second metal layer 12 through the bonding layer 50, and the semiconductor chip 21 may be bonded to the second metal layer 12 through the bonding layer 51. Here, the bonding layer 50 or 51 may include a solder layer or sintering layer.

The external connection frame 41 may be disposed on the semiconductor chips 20 and 21. The external connection frame 41 may have a lower surface bonded to both the semiconductor chip 20 and the semiconductor chip 21. In detail, the external connection frame 41 may have the lower surface bonded to the semiconductor chip 20 through the bonding layer 54 and bonded to the semiconductor chip 21 through the bonding layer 55. Here, the bonding layer 54 or 55 may include a solder layer or sintering layer.

The external connection frame 42 may be bonded to the second metal layer 13 through the bonding layer 52, the external connection frame 43 may be bonded to the second metal layer 12 through the bonding layer 53, and the semiconductor chip 21 and the second metal layer 12 may be connected to each other through the wire connection part 44. Here, the bonding layer 52 or 53 may include a solder layer or sintering layer. In some embodiments, the arrangement of the external connection frames 42 and 43 and the wire connection part 44 may depend on a specific implementation purpose. In some embodiments, the external connection frame 41, 42, or 43 may include copper (Cu).

The spacers 30 and 31 may be disposed on the external connection frame 41. The bondable metal layer 57 or 59 capable of being soldered or sintered may be disposed between the spacer 30 or 31 and the external connection frame 41. In some embodiments, the bondable metal layer 57 or 59 may include at least one material selected from silver (Ag) and copper (Cu). In some embodiments, the bondable metal layer 57 or 59 may be applied to a lower surface of the spacer 30 or 31. The spacer 30 or 31 and the external connection frame 41 may be bonded to each other through soldering or sintering. In detail, the bondable metal layer 57 or 59 and the external connection frame 41 may be bonded to each other through the bonding layer 56 or 58. Here, the bonding layer 56 or 58 may include a solder layer or sintering layer.

In some embodiments, the spacer 30 or 31 and the external connection frame 41 may be bonded to each other through direct copper bonding or active metal brazing in addition to soldering or sintering.

The spacer 30 or 31 may include at least one material selected from aluminum oxide (Al₂O₃), aluminum nitride (AlN), and silicon nitride (Si₃N₄). As the spacer 30 or 31 includes at least one material selected from aluminum oxide (Al₂O₃), aluminum nitride (AlN), and silicon nitride (Si₃N₄), the spacer 30 or 31 may have a high heat conduction feature along with an electrical insulation feature.

A spacer which is manufactured as an alloy of copper and molybdenum (CuMo) or an alloy of aluminum and carbon-based silicon (AlSiC) may have electrical conductivity lower than copper used in the board or the external connection frame (or lead frame), thus exhibiting a higher electrical resistance and a greater current loss. In contrast, in this embodiment, the spacer 30 or 31 may be formed using at least one material selected from aluminum oxide (Al₂O₃), aluminum nitride (AlN), and silicon nitride (Si₃N₄), thus exhibiting a lower current loss and excellent heat dissipation.

The molding part 60 may fill spaces between the boards 10, 11, 12, and 13 and the spacers 30 and 31. The molding part 60 may include, for example, an epoxy molding resin. The lower surface of the board 10, 11, 12, or 13 may be exposed to the outside through a lower surface of the molding part 60, and an upper surface of the spacer 30 or 31 may be exposed to the outside through an upper surface of the molding part 60. The lower surface of the board 10, 11, 12, or 13, which is exposed to the outside through the lower surface of the molding part 60, may be connected to a first external cooling structure to dissipate heat, and the upper surface of the spacer 30 or 31, which is exposed to the outside through the upper surface of the molding part 60, may be connected to a second external cooling structure to dissipate heat. Here, the first cooling structure and the second cooling structure may be a single cooling structure or may be separate cooling structures physically distinguished from each other.

In this embodiment, the semiconductor chips 20 and 21 may include the first semiconductor chip 20 having a first width, and the second semiconductor chip 21 having a second width greater than the first width. In addition, the spacers 30 and 31 may include the first spacer 30 having a third width corresponding to the first width, and the second spacer 31 having a fourth width corresponding to the second width and larger than the third width. Here, the external connection frame 41 may have the lower surface bonded to both the first semiconductor chip 20 and the second semiconductor chip 21 and the upper surface bonded to both the first spacer 30 and the second spacer 31.

According to these embodiments, the current may connected to the outside through the external copper connection frame 41 bonded to an upper part of the semiconductor chip 20 or 21 by adopting the spacer 30 or 31 having the electrical insulation feature and the high heat conduction feature, and heat occurring therein may be dissipated to the external cooling structure through the spacer 30 or 31 having the electrical insulation feature and the high heat conduction feature, thereby lowering the current loss caused by the conventional spacer having the higher electrical resistance and securing the excellent heat dissipation. In addition, the heat dissipation may be maximized while minimizing a volume occupied by the spacer in the package by individually forming the spacers 30 and 31 each having a size appropriate for the width of each of the semiconductor chips 20 and 21.

In addition, when performing a manufacturing process by using over molding, there is a risk of cracks occurring in an upper board because a mold compound may fail to fill a large area due to warpage of the upper board having the large area. However, in the embodiments, this risk may be resolved by forming the smaller-sized spacer 30 or 31 as the heat sink on the individual semiconductor chip. Meanwhile, in a conventional method of applying the spacer and a wide upper board, a mold flow may not be smooth, which may cause a risk of delamination between the upper board and the mold compound and a risk of unfilling around the spacer. However, in these embodiments, the flow may be improved by providing the smaller-sized spacer 30 or 31.

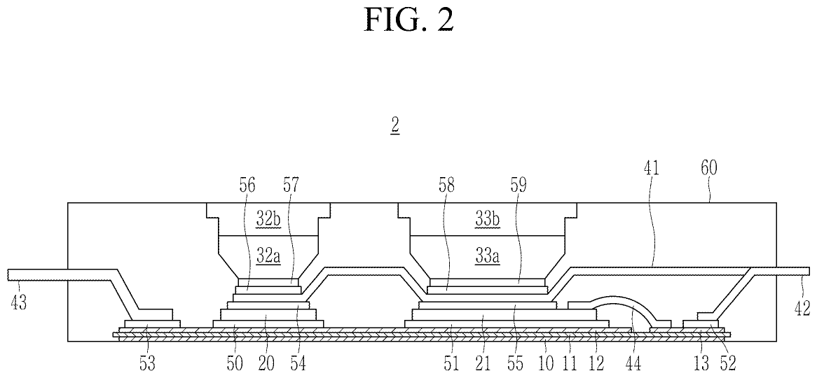

FIG. 2 is a diagram for explaining a double sided cooling semiconductor device according to an embodiment.

Referring to FIG. 2, a double sided cooling semiconductor device 2 according to an embodiment may include the boards 10, 11, 12, and 13, the semiconductor chips 20 and 21, spacers 32a, 32b, 33a, and 33b, the external connection frames 41, 42, and 43, the wire connection part 44, the bonding layers 50, 51, 52, 53, 54, 55, 56, and 58, the bondable metal layers 57 and 59, and the molding part 60. Descriptions of the boards 10, 11, 12, and 13, the semiconductor chips 20 and 21, the external connection frames 41, 42, and 43, the wire connection part 44, the bonding layers 50, 51, 52, 53, 54, 55, 56, and 58, the bondable metal layers 57 and 59, and the molding part 60 may refer to the descriptions provided above with reference to FIG. 1, and their redundant descriptions are thus omitted here.

The spacers 32a, 32b, 33a, and 33b may include the lower spacers 32a and 33a and the upper spacers 32b and 33b. The lower spacer 32a or 33a and the upper spacer 32b or 33b may be bonded to each other through direct copper bonding or active metal brazing. Here, the lower spacer 32a or 33a may include at least one material selected from aluminum oxide (Al₂O₃), aluminum nitride (AlN), and silicon nitride (Si₃N₄), and the upper spacer 32b or 33b may include at least one material selected from copper (Cu) and aluminum (Al).

The spacers 32a, 32b, 33a, and 33b may be disposed on the external connection frame 41. The bondable metal layers 57 and 59 capable of being soldered or sintered may be disposed between the spacers 32a, 32b, 33a, and 33b and the external connection frame 41. In some embodiments, the bondable metal layer 57 or 59 may include at least one material selected from silver (Ag) and copper (Cu). In some embodiments, the bondable metal layer 57 or 59 may be applied to a lower surface of the lower spacer 32a or 33a. The lower spacer 32a or 33a and the external connection frame 41 may be bonded to each other through soldering or sintering. In detail, the bondable metal layer 57 or 59 and the external connection frame 41 may be bonded to each other through the bonding layer 56 or 58. Here, the bonding layer 56 or 58 may include the solder layer or sintering layer.

In some embodiments, the spacers 32a, 32b, 33a, and 33b and the external connection frame 41 may be bonded to one another through direct copper bonding or active metal brazing in addition to soldering or sintering.

In this embodiment, the semiconductor chips 20 and 21 may include the first semiconductor chip 20 having the first width, and the second semiconductor chip 21 having the second width greater than the first width. In addition, the spacers 32a, 32b, 33a, and 33b may include the first spacers 32a and 32b having the third width corresponding to the first width, and the second spacers 33a and 33b having the fourth width corresponding to the second width and larger than the third width. Here, the external connection frame 41 may have the lower surface bonded to both the first semiconductor chip 20 and the second semiconductor chip 21, and the external connection frame 41 may have the upper surface bonded to all the first spacers 32a and 32b and the second spacers 33a and 33b.

According to these embodiments, the current may connected to the outside through the external copper connection frame 41 bonded to on the upper part of the semiconductor chip 20 or 21 by adopting the spacers 32a and 32b or 33a and 33b, each having the electrical insulation feature and the high heat conduction feature, and heat occurring therein may be dissipated to the external cooling structure through the spacers 32a and 32b or 33a and 33b, each having the electrical insulation feature and the high heat conduction feature, thereby lowering the current loss caused by the conventional spacer having the higher electrical resistance and securing the excellent heat dissipation.

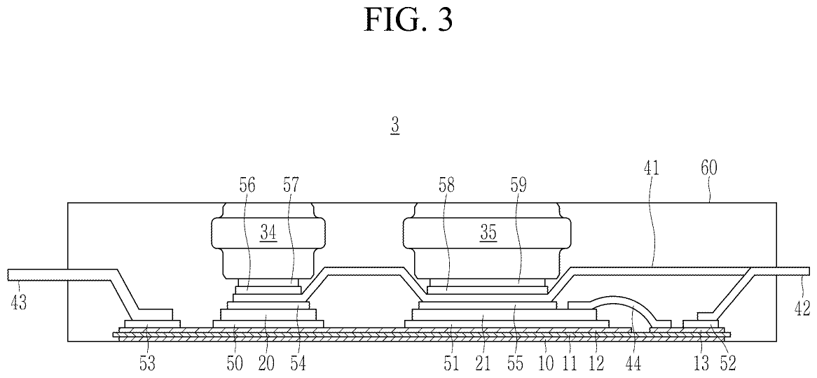

FIG. 3 is a diagram for explaining a double sided cooling semiconductor device according to an embodiment.

Referring to FIG. 3, a double sided cooling semiconductor device 3 according to an embodiment may include the boards 10, 11, 12, and 13, the semiconductor chips 20 and 21, spacers 34 and 35, the external connection frames 41, 42, and 43, the wire connection part 44, the bonding layers 50, 51, 52, 53, 54, 55, 56, and 58, the bondable metal layers 57 and 59, and the molding part 60. Descriptions of the boards 10, 11, 12, and 13, the semiconductor chips 20 and 21, the external connection frames 41, 42, and 43, the wire connection part 44, the bonding layers 50, 51, 52, 53, 54, 55, 56, and 58, the bondable metal layers 57 and 59, and the molding part 60 may refer to the descriptions provided above with reference to FIG. 1, and their redundant descriptions are thus omitted here.

The spacer 34 or 35 may include an insulating material made of ceramic and include a curved part. As shown in the drawing, the spacer 34 or 35 may have a second part corresponding to the middle between its lower part and upper part and having a width greater than a width of a first part corresponding to the lower part or the upper part. Accordingly, the second part may protrude further to the left and right than the first part. At a protruding portion of the second part, a contour that is bent at an angle of 90 degrees may be formed at a point where the upper or lower surface of the second part that extends in a horizontal direction meets a side surface of the first part that extends in a vertical direction, which may be referred to as the curved part. The curved part may lower a stress on the spacer 34 or 35 and reduce the risk of cracks. That is, the curved part may be formed as a step when molding the spacer 34 or 35, and suppress moisture absorption and the development of cracks/delamination. In some embodiments, the curved part may have the protruding portion whose length is 0.5 mm or more.

The spacers 34 and 35 may be disposed on the external connection frame 41. The bondable metal layer 57 or 59 capable of being soldered or sintered may be disposed between the spacer 34 or 35 and the external connection frame 41. In some embodiments, the bondable metal layer 57 or 59 may include at least one material selected from silver (Ag) and copper (Cu). In some embodiments, the bondable metal layer 57 or 59 may be applied to a lower surface of the spacer 34 or 35. The spacer 34 or 35 may be made of ceramic. Therefore, the spacer 34 or 35 may not be bonded to the external connection frame 41 by directly applying soldering or sintering, and the bondable metal layer 57 or 59 and the external connection frame 41 may be bonded to each other through the bonding layer 56 or 58. Here, the bonding layer 56 or 58 may include the solder layer or sintering layer.

In some embodiments, the spacer 34 or 35 and the external connection frame 41 may be bonded to each other through direct copper bonding or active metal brazing in addition to soldering or sintering.

In this embodiment, the semiconductor chips 20 and 21 may include the first semiconductor chip 20 having the first width, and the second semiconductor chip 21 having the second width greater than the first width. In addition, the spacers 34 and 35 may include the first spacer 34 having the third width corresponding to the first width, and the second spacer 35 having the fourth width corresponding to the second width and larger than the third width. Here, the external connection frame 41 may have the lower surface bonded to both the first semiconductor chip 20 and the second semiconductor chip 21 and the upper surface bonded to both the spacers 34 and 35.

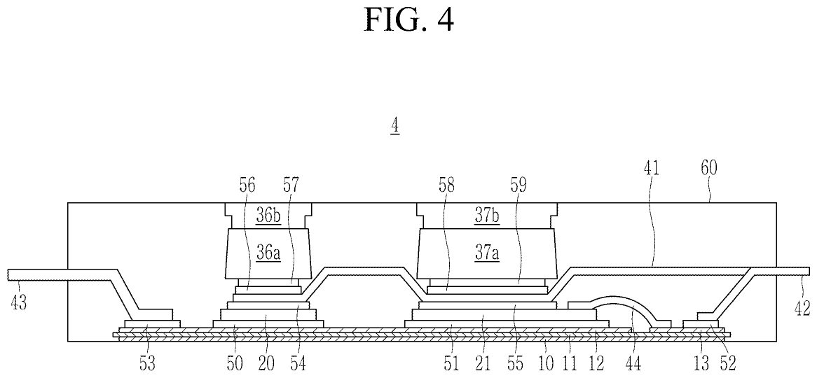

FIG. 4 is a diagram for explaining a double sided cooling semiconductor device according to an embodiment.

Referring to FIG. 4, a double sided cooling semiconductor device 4 according to an embodiment may include the boards 10, 11, 12, and 13, the semiconductor chips 20 and 21, spacers 36a, 32b, 37a, and 33b, the external connection frames 41, 42, and 43, the wire connection part 44, the bonding layers 50, 51, 52, 53, 54, 55, 56, and 58, the bondable metal layers 57 and 59, and the molding part 60. Descriptions of the boards 10, 11, 12, and 13, the semiconductor chips 20 and 21, the external connection frames 41, 42, and 43, the wire connection part 44, the bonding layers 50, 51, 52, 53, 54, 55, 56, and 58, the bondable metal layers 57 and 59, and the molding part 60 may refer to the descriptions provided above with reference to FIG. 1, and their redundant descriptions are thus omitted here.

The spacers 36a, 36b, 37a, and 37b may include the lower spacers 36a and 37a and the upper spacers 36b and 37b. In some embodiments, the lower spacer 36a or 37a and the upper spacer 36b or 37b may be bonded to each other through direct copper bonding or active metal brazing. Here, the lower spacer 36a or 37a may include the insulating material made of ceramic, and the upper spacer 36b or 37b may include at least one material selected from copper (Cu) and aluminum (Al). Compared to the spacer structure in FIG. 3, the spacer structure in FIG. 4 may exhibit further improved heat dissipation by replacing a portion of ceramic with copper (Cu), aluminum (Al), or the like, and protect the lower spacer 36a or 37a against an external impact by using the upper spacer 36b or 37b.

The spacers 36a, 36b, 37a, and 37b may be disposed on the external connection frame 41. The bondable metal layers 57 and 59 capable of being soldered or sintered may be disposed between the spacers 36a, 36b, 37a, and 37b and the external connection frame 41. In some embodiments, the bondable metal layer 57 or 59 may include at least one material selected from silver (Ag) and copper (Cu). In some embodiments, the bondable metal layer 57 or 59 may be applied to a lower surface of the spacer 36a or 37a. The lower spacer 36a or 37a may be made of ceramic. Therefore, the lower spacer 36a or 37a may not be bonded to the external connection frame 41 by directly applying soldering or sintering, and the bondable metal layer 57 or 59 and the external connection frame 41 may be bonded to each other through the bonding layer 56 or 58. Here, the bonding layer 56 or 58 may include the solder layer or sintering layer.

In some embodiments, the spacers 36a, 36b, 37a, and 37b and the external connection frame 41 may be bonded to one another through direct copper bonding or active metal brazing in addition to soldering or sintering.

In this embodiment, the semiconductor chips 20 and 21 may include the first semiconductor chip 20 having the first width, and the second semiconductor chip 21 having the second width greater than the first width. In addition, the spacers 36a, 36b, 37a, and 37b may include the first spacers 36a and 36b having the third width corresponding to the first width, and the second spacers 37a and 37b having the fourth width corresponding to the second width and larger than the third width, based on the maximum width. Here, the external connection frame 41 may have the lower surface bonded to both the first semiconductor chip 20 and the second semiconductor chip 21 and the upper surface bonded to all the first spacers 36a and 36b and the second spacers 37a and 37b.

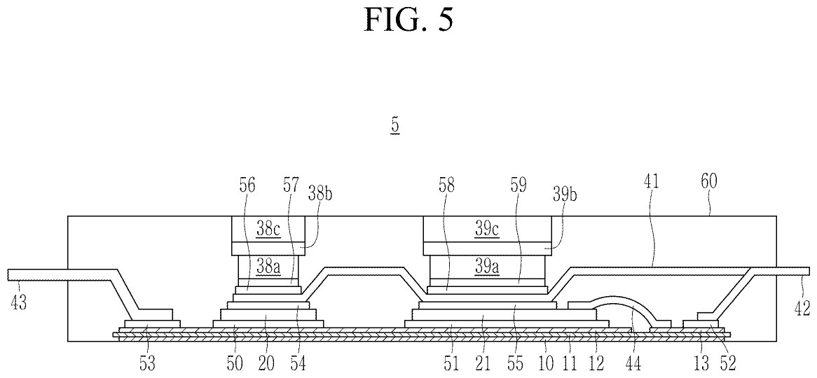

FIG. 5 is a diagram for explaining a double sided cooling semiconductor device according to an embodiment.

Referring to FIG. 5, a double sided cooling semiconductor device 5 according to an embodiment may include the boards 10, 11, 12, and 13, the semiconductor chips 20 and 21, spacers 38a, 38b, 38c, 39a, 39b, and 39c, the external connection frames 41, 42, and 43, the wire connection part 44, the bonding layers 50, 51, 52, 53, 54, 55, 56, and 58, the bondable metal layers 57 and 59, and the molding part 60. Descriptions of the boards 10, 11, 12, and 13, the semiconductor chips 20 and 21, the external connection frames 41, 42, and 43, the wire connection part 44, the bonding layers 50, 51, 52, 53, 54, 55, 56, and 58, the bondable metal layers 57 and 59, and the molding part 60 may refer to the descriptions provided above with reference to FIG. 1, and their redundant descriptions are thus omitted here.

The spacers 38a, 38b, 38c, 39a, 39b, and 39c may include the lower spacers 38a and 39a, the middle spacers 38b and 39b, and the upper spacers 38c and 39c. In some embodiments, the lower spacers 38a and 39a, the middle spacers 38b and 39b, and the upper spacers 38c and 39c may be bonded to one another through direct copper bonding or active metal brazing. Here, the lower spacer 38a or 39a and the upper spacer 38c or 39c may each include at least one material selected from copper (Cu) and aluminum (Al), and the middle spacer 38b or 39b may include the insulating material made of ceramic.

Compared to the spacer structure in FIG. 3, the spacer structure in FIG. 5 may implement an excellent heat dissipation feature by minimizing a thickness of ceramic, and protect the middle spacer 38b or 39b against the external impact by using the upper spacer 38c or 39c.

The spacers 38a, 38b, 38c, 39a, 39b, and 39c may be disposed on the external connection frame 41. The bondable metal layers 57 and 59 capable of being soldered or sintered may be disposed between the spacers 38a, 38b, 38c, 39a, 39b, and 39c and the external connection frame 41. In some embodiments, the bondable metal layer 57 or 59 may include at least one material selected from silver (Ag) and copper (Cu). In some embodiments, the bondable metal layer 57 or 59 may be applied to a lower surface of the lower spacer 38a or 39a. The lower spacer 38a or 39a and the external connection frame 41 may be bonded to each other through soldering or sintering. In detail, the bondable metal layer 57 or 59 and the external connection frame 41 may be bonded to each other through the bonding layer 56 or 58. Here, the bonding layer 56 or 58 may include the solder layer or sintering layer.

In some embodiments, the spacers 38a, 38b, 38c, 39a, 39b, and 39c and the external connection frame 41 may be bonded to one another through direct copper bonding or active metal brazing in addition to soldering or sintering.

In this embodiment, the semiconductor chips 20 and 21 may include the first semiconductor chip 20 having the first width, and the second semiconductor chip 21 having the second width greater than the first width. In addition, the spacers 38a, 38b, 38c, 39a, 39b, and 39c may include the first spacers 38a, 38b, and 38c having the third width corresponding to the first width, and the second spacers 39a, 39b, and 39c having the fourth width corresponding to the second width and larger than the third width, based on the maximum width. Here, the external connection frame 41 may have the lower surface bonded to both the first semiconductor chip 20 and the second semiconductor chip 21 and the upper surface bonded to all the first spacers 38a, 38b, and 38c and the second spacers 39a, 39b, and 39c.

According to these embodiments described above, the current may connected to the outside through the external copper connection frame bonded to the upper part of the semiconductor chip by adopting the spacer having the electrical insulation feature and the high heat conduction feature, and heat occurring therein may be dissipated to the external cooling structure through the spacer having the electrical insulation feature and the high heat conduction feature, thereby lowering the current loss caused by the conventional spacer having the higher electrical resistance and securing the excellent heat dissipation. In addition, the individual spacer having a size appropriate for each semiconductor chip may be provided, thereby maximizing the heat dissipation while minimizing the volume of the spacer in the package.

Although the embodiments of the disclosure have been described in detail hereinabove, the scope of the disclosure is not limited thereto. That is, various modifications and alterations made by those skilled in the art to which the disclosure pertains by using a basic concept of the disclosure as defined in the following claims also fall within the scope of the disclosure.

1. A double sided cooling semiconductor device comprising:
a board;
a semiconductor chip disposed on the board;
an external connection frame disposed on the semiconductor chip;
a spacer disposed on the external connection frame; and
a molding part filling a space between the board and the spacer,
wherein a lower surface of the board is exposed to the outside through a lower surface of the molding part, and
an upper surface of the spacer is exposed to the outside through an upper surface of the molding part.

2. The device of claim 1, wherein
the spacer includes at least one material selected from aluminum oxide (Al₂O₃), aluminum nitride (AlN), and silicon nitride (Si₃N₄).

3. The device of claim 1, wherein
the lower surface of the board, which is exposed to the outside through the lower surface of the molding part, is connected to a first external cooling structure to dissipate heat, and the upper surface of the spacer, which is exposed to the outside through the upper surface of the molding part, is connected to a second external cooling structure to dissipate heat.

4. The device of claim 1, wherein
a bondable metal layer capable of being soldered or sintered is disposed between the spacer and the external connection frame, and
the spacer and the external connection frame are bonded to each other through soldering or sintering.

5. The device of claim 4, wherein
the bondable metal layer is applied to a lower surface of the spacer.

6. The device of claim 1, wherein
the spacer and the external connection frame are bonded to each other through direct copper bonding or active metal brazing.

7. The device of claim 1, wherein
the spacer includes the lower spacer and the upper spacer, and
the lower spacer and the upper spacer are bonded to each other through direct copper bonding or active metal brazing.

8. The device of claim 7, wherein
the lower spacer includes at least one material selected from aluminum oxide (Al₂O₃), aluminum nitride (AlN), and silicon nitride (Si₃N₄), and
the upper spacer includes at least one material selected from copper (Cu) and aluminum (Al).

9. The device of claim 1, wherein
the spacer includes an insulating material made of ceramic and includes a curved part.

10. The device of claim 7, wherein
the lower spacer includes an insulating material made of ceramic, and
the upper spacer includes at least one material selected from copper (Cu) and aluminum (Al).

11. The device of claim 1, wherein
the spacer includes the lower spacer, the middle spacer, and the upper spacer, and
the lower spacer, the middle spacer, and the upper spacer are bonded to one another through direct copper bonding or active metal brazing.

12. The device of claim 11, wherein
the lower spacer and the upper spacer each include at least one material selected from copper (Cu) and aluminum (Al), and
the middle spacer includes an insulating material made of ceramic.

13. The device of claim 1, wherein
the board is a direct bonded copper (DBC) board, and
the board includes a first metal layer, a second metal layer, and a ceramic layer formed between the first metal layer and the second metal layer.

14. The device of claim 1, wherein
the semiconductor chip includes a first semiconductor chip having a first width, and a second semiconductor chip having a second width greater than the first width,
the spacer includes the first spacer having a third width corresponding to the first width, and the second spacer having a fourth width corresponding to the second width and larger than the third width, and
the external connection frame has a lower surface bonded to both the first semiconductor chip and the second semiconductor chip and an upper surface bonded to both the first spacer and the second spacer.
